(19) United States
(12) Patent Application Publication
(10) Pub. No.: US 2014/0021940 A1
(43) Pub. Date: Jan. 23, 2014

(54) ELECTRIC POWER MONITORING DEVICE AND AN APPARATUS USING ALTERNATING CURRENT POWER HAVING THE SAME

(71) Applicants: Jung Eui HONG, Yongin-Si (KR); J. OCEAN Co., Ltd., Yongin-Si (KR)

(72) Inventor: Jung Eui HONG, Yongin-Si (KR)

(21) Appl. No.: 13/910,088

(22) Filed: Jun. 4, 2013

(30) Foreign Application Priority Data
Jul. 20, 2012 (KR) 10-2012-0079381

(51) Int. Cl. G01R 21/06

(52) U.S. Cl. CPC G01R 21/06
USPC 324/142; 324/76.11

(57) ABSTRACT

The present invention relates to an electric power monitoring device, and particularly to an electric power monitoring device for monitoring a quality of alternating current power. According to an embodiment of the present invention, an electric power monitoring device is provided with a first connection portion, a second connection portion and a cable that connects the first connection portion to the second connection portion and comprises a measuring unit for measuring alternating current power quality; a processing unit which is connected to the measuring unit to convert the measured power quality to data; and a display which is connected to the processing unit to display the data on a screen. The electric power monitoring device is used for an apparatus having an alternating current power input unit.

### TECHNICAL FIELD

The present invention relates to an electric power monitoring device and an apparatus using alternating current power, and particularly to an electric power monitoring device and an apparatus using alternating current power for monitoring a quality of alternating current power.

### BACKGROUND

Recently, an ability to perceive, understand and solve problems relating to electric power quality directly becomes increasingly important in the industry using various facilities using electric power. To date, companies receive electric power and ask experts for help when a problem occurs. However, now they want to analyze and solve quality problems directly to reduce energy waste.

Problems relating to electric power quality are divided into short-term fluctuation and long-term fluctuation. The short-term fluctuation includes voltage drop, voltage build up and black out, and the long-term fluctuation includes black out holding, undervoltage, overvoltage, voltage unbalance and frequency fluctuation.

When such electric power quality problems are generated, the operation of apparatus may be ceased. Such cessation of facility and apparatus results in earning deterioration. Therefore, an electric power monitoring device to provide information for rapid analysis, understand and solution of problematic situations is importantly emphasized.

In order to install an electric power monitoring device in a conventional apparatus using alternating current power, a space where the electric power monitoring device may be additionally installed is greatly restricted due to an existing apparatus securely fixed on a floor. Also, the electric power of facility and apparatus is cut off during the installation of electric power monitoring device. As a result, the operation of apparatus is ceased for the time required for the installation and money losses is caused.

As an attempt to solve such problems, a portable electric power analyzer is used. However, such an analyzer cannot analyze electric power quality in real time, but it is used to understand a problematic situation after an electric power problem is generated.

Moreover, since the analyzer does not provide information on a correct time point when a problem relating to electric power quality is generated, it is difficult to perceive the position and time that the problem is generated. Therefore, it is a challenge to give user information to prevent a fundamental electric power quality problem.

### PRIOR ART DOCUMENT

### Patent Document

(Patent Document 1) KR 10-2007-0009831 A

### SUMMARY

### Problems to be Solved

The present invention provides an electric power monitoring device which can be simply installed without an alteration or exchange of existing facilities and apparatuses. Also, the present invention provides an electric power monitoring device which can monitor electric power quality in real time.

### Means to Solve the Problems

According to an embodiment of the present invention, it is provided herein an electric power monitoring device for use in an apparatus having an alternating current power input unit, comprising a measuring unit for measuring alternating current power quality, being provided with a first connection portion, a second connection portion and a cable that connects the first connection portion to the second connection portion; a processing unit which is connected to the measuring unit to convert the measured power quality to data; and a display which is connected to the processing unit to display the data on a screen.

Further, the first connection portion comprises the same shape as the shape of the input unit, and the second connection portion comprises the same shape as the shape of a line for supplying the alternating current power.

Further, the measuring unit comprises a current transformer through which the cable passes to measure a current of the alternating current power and a measurement cable which is connected to the cable to measure a voltage of the alternating current power.

Further, the measuring unit comprises a housing accommodating the current transformer and the measurement cable.

Further, the processing unit comprises a housing accommodating at least a portion of the processing unit and to mount the display on its one side, which is rotatably connected to the measuring unit housing.

Further, the measuring unit and the processing unit may be accommodated within separate housings spaced apart from each other.

Further, a rotation unit with a rotational axis is coupled between the measuring unit housing and the processing unit housing.

Further, the processing unit comprises at least one of memory units and communication ports that are disposed within the processing unit housing with one end extending outwardly from the processing unit housing.

Further, a power supply for supplying power is disposed within the measuring unit housing with one end being connected to the cable.

Further, the measuring unit and the processing unit may be connected wired or wireless.

Further, a plurality of measuring units may be provided, and the processing unit may be connected to the plurality of measuring units.

Further, according to an embodiment of the present invention, it is provided herein a device using alternating current power, comprising an apparatus which uses alternating current power and has an input unit connected to the alternating current power, and an electric power monitoring device which is removably connected between a line for supplying the alternating current power and the input unit to monitor the quality of the alternating current power.

Further, the electric power monitoring device comprises a measuring unit having a first connection portion coupled to the line and a second connection portion coupled to the input unit.

Further, the measuring unit comprises a measuring unit housing, a cable that is disposed within the measuring unit housing and connected to the first and second connection portions, a non-contact type current measuring device for measuring a current from the cable, and a contact type voltage measuring device for measuring a voltage from the cable.

Further, the electric power monitoring device comprises a processing unit housing accommodating at least a portion of a processing unit and to mount a display on its one side, which is rotatably connected to the measuring unit housing.

Further, according to an embodiment of the present invention, it is provided herein a method for monitoring electric power quality, comprising the steps of providing an electric power monitoring device, inserting the electric power monitoring device between an electric power supplying line and an apparatus using electric power, and monitoring the quality of the electric power by the electric power monitoring device.

Further, the electric power is at least one of single-phase, three-phase and four-phase alternating current powers, and the apparatus includes semiconductor or display manufacturing apparatuses.

Further, the electric power monitoring device comprises measuring a current, a voltage and a phase of the electric power, converting the measured values to data, and comparing the data with set values pre-inputted from user.

Further, the step of monitoring the quality of the electric power is provided with a cable that connects the line to the input unit and comprises the step of measuring the current not in contact with the cable.

Further, the step of monitoring the quality of the electric power comprises measuring the voltage and the phase in contact with the cable.

Further, the monitoring comprises performing at least one of data recordation, data analysis, data plotting, transmission and storage of data to outside after format transformation, comparison of with set values, and warning signal generation.

### Effect of the Invention

According to an embodiment of the present invention, an electric power monitoring device can be simply installed without an alteration or exchange of existing facilities and apparatuses. Also, the electric power monitoring device can be simply installed in a restricted space, and a structural alteration of existing apparatuses is not required for the installation to reduce the cost and time required for the installation.

Moreover, a separate tool such as probe is not required for monitoring electric power, and a separate power supply (such as battery and outer power cable) for operating the electric power monitoring device may be omitted.

Furthermore, such a monitoring is performed by measuring in real time information (such as voltage, current, effective power, reactive power, apparent power, power factor, frequency, phase, temperature, energy, and the like) on electric power supplied to a facility.

Further, the supplied electric power is measured in real time and the measured values are converted to data, stored and analyzed to understand easily information on electric power quality. Consequently, a facility or an apparatus may be systematically managed. Also, a fluctuation in electric power and apparatus condition is previously determined based on the measured values before a problem relating to electric power quality is generated, and a risk is warned in advance.

Further, the condition and fluctuation of electric power quality are presented as data to perceive easily in real time the power consumption of each of facilities and apparatuses. Consequently, facilities and apparatuses may be compared with each other to develop high efficiency facilities which may reduce power consumption.

Further, the supplied electric power is monitored in real time to predict a variation in condition of facility in advance. Consequently, the facility may be effectively managed, repaired and operated.

### BRIEF DESCRIPTION OF THE DRAWINGS

FIG. 1 is a schematic view showing a device using alternating current power provided with an electric power monitoring device according to an embodiment of the present invention.

FIG. 2 is an exploded view showing an electric power monitoring device according to an embodiment of the present invention.

FIG. 3 shows (a) a front view, (b) a rear view, (c) a right side view, (d) a left side view and (e) a planar view of an electric power monitoring device according to an embodiment of the present invention.

FIG. 4 shows the configuration of an electric power monitoring device according to a modified embodiment of the present invention.

FIG. 5 is a flow chart illustrating a method for monitoring electric power quality according to an embodiment of the present invention.

FIG. 6 is a block diagram illustrating a method for monitoring electric power quality according to an embodiment of the present invention.

### DETAILED DESCRIPTION OF THE INVENTION

Now, embodiments according to the present invention will be described in detail with reference to the accompanying drawings. However, the present invention is not limited to these embodiments described below, but it may be embodied as different configurations. These embodiments are provided for a full understanding of the present invention, and the scope of the present invention may be fully understood by one with ordinary skill in the art with reference to these embodiments. A thickness in the drawings is enlarged to display clearly a variety of layers and regions. Like numbers in the drawing represent like elements. As used herein, the term connection is intended to cover a wide range of meanings including at least one of physical connection, electrical connection, wireless communication connection and mechanical connection.

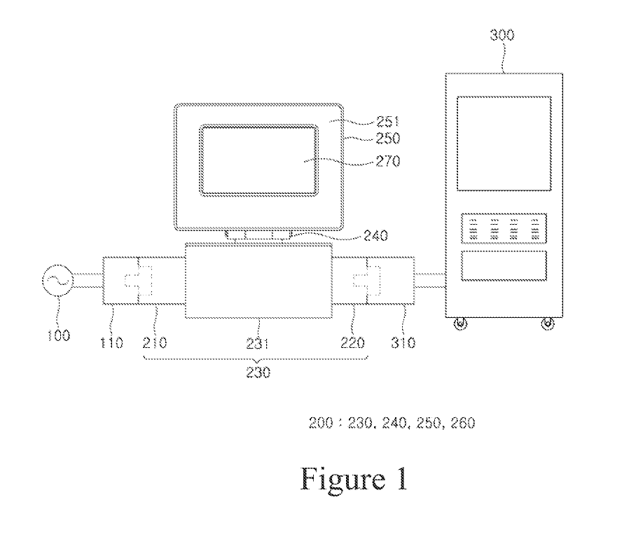

FIG. 1 is a schematic view showing a device using alternating current power provided with an electric power monitoring device according to an embodiment of the present invention.

The device using alternating current power comprises an electric power monitoring device (200) and an apparatus (300) having an input unit (310) which operates using alternating current power. The alternating current power refers to common alternating current power used in various industries, and includes single-phase, single-phase three-wire, three-phase four-wire systems and like that. The single-phase system supplies alternating current power using two wires, the single-phase three-wire system supplies-single-phase electric power using three wires, and the three-phase four-wire system supplies three-phase electric power using four wires. An alternating current power line (100) refers to means for supplying electric power, and includes utilities used in plants and others. An end (110) of the alternating current power line (100) has a shape conforming to the input unit (310) of the apparatus and is connected to the apparatus (300) using alternating current power. That is, the end (110) has a shape to engage with the input unit (310) of the apparatus (300). The electric power monitoring device (200) is coupled between the end (110) and the input unit (310). Also, the apparatus (300) may be directly connected to the alternating current power to operate it without the electric power monitoring device (200). The electric power monitoring device (200) has connection portions for engaging with the end (110) and the input unit (310). For example, each connection portion (210 and 220) and the end (110) and the input unit (310) have connectors for inter-engagement, a connector of the first connection portion (210) has the same shape as a connector of the input unit (310) to be connected to the end (110) of the alternating current power line (100), and a connector of the second connection portion (220) has the same shape as a connector of the end (110) of the alternating current power line (100) to be connected to the input unit (310) of the apparatus (300). Thus, the electric power monitoring device (200) can be installed without a damage or destruction of existing connection portions in the apparatus, and allows to reduce time required for installation and cost damage due to apparatus stopping during installation. The first connection portion (210) is not limited to single shape, and may have shapes conforming to a shape of the end (110) of the alternating current power line (100) to be connected. Also, the second connection portion (220) is not limited to single shape, and may have shapes conforming to a shape of the input unit (310) of the apparatus (300) to be connected.

The apparatus (300) using alternating current power operates using any one of single-phase, three-wire and four-wire systems, and is used for example in electric power and communication companies, airplane, expensive high-tech medical devices, ship, railroad, production facilities of large plants. Among others, applications for expensive apparatus for producing a semiconductor or a display are illustrated in embodiments of the present invention.

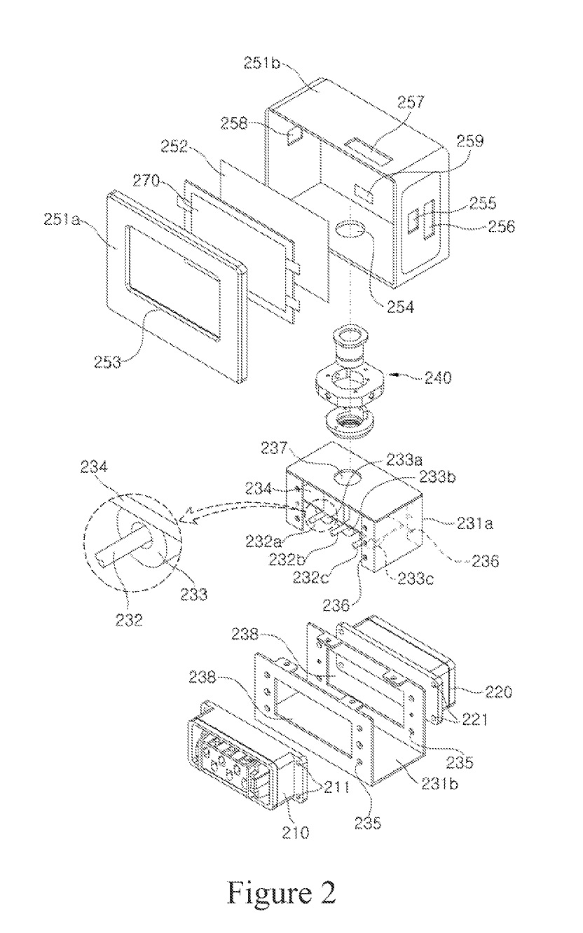

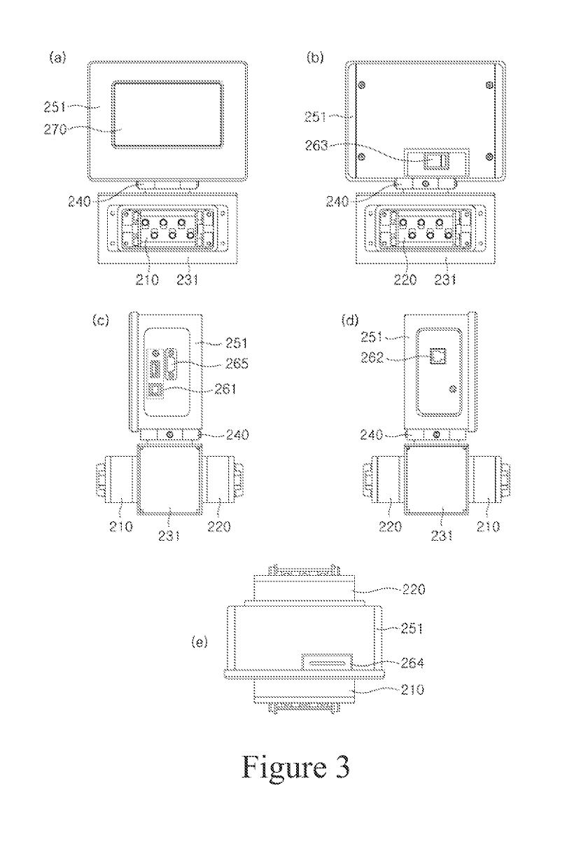

FIG. 2 is an exploded view showing an electric power monitoring device according to an embodiment of the present invention, and FIG. 3 shows (a) a front view, (b) a rear view, (c) a right side view, (d) a left side view and (e) a planar view of an electric power monitoring device according to an embodiment of the present invention.

The electric power monitoring device (200) comprises a measuring unit (230) for measuring electric power quality, a processing unit (250) for converting the measured electric power quality to data, a rotation unit (240) by which the processing unit (250) is rotatably connected to the measuring unit (230), and a display (270) connected to the processing unit (250) to display the data on a screen.

The measuring unit (230) has an inner space in which a measuring member (such as current measuring device and voltage measuring device) is installed and comprises a first housing (231: 231a, 231b) with one side connected to the first connection portion (210) and the other side connected to the second connection portion (220); the first connection portion (210) with one end connected to the end (110) of the alternating current power line and the other end connected to one side of the first housing (231: 231a, 231b); the second connection portion (220) with one end connected to the input unit (310) of the apparatus using electric power and the other end connected to the other side of the first housing(231: 231a, 231b); and connection cables (232: 232a, 232b, 232c) that connects the first connection portion (210) to the second connection portion (220).

The first housing (231: 231a, 231b) has an inner space formed by coupling an upper housing (231a) and a lower housing (231b) and the inner space accommodates various members including connection cables, measuring devices and circuit boards.

The upper housing (231a) comprises a top plate having a length extending horizontally and left and right plates connected to both ends of the top plate. The left and right plates are disposed facing in parallel each other. Also, the left and right plates are provided with edge plates which are bent in front and back. The edge plates have through holes (236) and are connected to through holes (235) provided in both sides of the lower housing (231b) and through holes provided in the first and second connection portions (210 and 220) using a connecting member (such as bolt and nut). That is, an overall form having a curved section of ‘ [symbol] ’-shape is made. The top plate of the upper housing (231a) comprises a through hole for a connection with the rotation unit (240) at its center. The bottom surface of the top plate has a measurement circuit board (234) installed to measure supply power.

The measurement circuit board (234) is installed within the inner space of the first housing (231: 231a, 231b), and a plurality of current measuring devices (233: 233a, 233b, 233c) which measure currents from connection cables (232: 232a, 232b, 232c) in non-contact manner, voltage measuring devices (not shown) which measure voltages from connection cables (232: 232a, 232b, 232c) in contact manner, and a signal transformer (not shown) which converts measurements from the current measuring devices (233: 233a, 233b, 233c) and the voltage measuring device (not shown) to digital signals are coupled to the top or bottom surfaces of the measurement circuit board (234).

The connection cables (232: 232a, 232b, 232c) are connection conduits which inter-connects the first connection portion (210) and the second connection portion (220), as described in detail below. That is, the ends of connection cables (232: 232a, 232b, 232c) are connected to the first connection portion (210) and the other ends are connected to the second connection portion (220). The connection cables (232: 232a, 232b, 232c) which are connected to the end of the first connection portion (210) inside the first housing (231: 231a, 231b) are connected to the end of the second connection portion (220) inside the first housing (231: 231a, 231b) through inner spaces provided in the plurality of current measuring devices (233: 233a, 233b, 233c), respectively. That is, the connection cables (232: 232a, 232b, 232c) connect the first connection portion (210) and the second connection portion (230) in the interior of the measuring unit (230).

The number of the connection cables (232: 232a, 232b, 232c) provided in the interior of the measuring unit (230) may be varied depending on the mode of alternating current supplied from the power line (100). Since the connection cables (232: 232a, 232b, 232c) connect the end (110) of the alternating current power line (100) to the input unit (310) of the apparatus (300) using alternating current power, the apparatus (300) using alternating current power may be normally operated even when causing a problem during the operation of the electric power monitoring device (200).

The plurality of current measuring devices (233: 233a, 233b, 233c) are formed as a doughnut-like circular ring with one side connected to the measurement circuit board (234). The above described connection cables (232: 232a, 232b, 232c) each pass through a circular inner space formed in the plurality of current measuring devices (233: 233a, 233b, 233c) to measure a current of the alternating current power in non-contact manner.

The voltage measuring device (not shown) is connected to a measurement cable (not shown) and the measurement circuit board (234). To measure a voltage and a phase of the alternating current power, additionally the voltage measuring device (not shown) is in contact with the connection cables (232: 232a, 232b, 232c) to measure the voltage and the phase in contact manner. For example, by connecting the measurement cable (not shown) to the connection cables (232: 232a, 232b, 232c), the voltage and the phase may be measured through the measurement cable.

The first housing (231) has the plurality of current measuring devices (234), the voltage measuring device (not shown), the connection cable (232) and the measurement cable (not shown) installed in the inner space to measure the alternating current power supplied from the power line. Thus, a consumed accessory (such as measuring probe) is not necessary to measure the alternating current power, which is connected to the electric power monitoring device at its one end and is connected to a measured target at a portion exposed to outside. It is advantageous in that an additional cost for management is not generated during the operation of the electric power monitoring device.

The signal transformer (not shown) which is installed inside the first housing (231) transforms analog signals from the alternating current power measured by the voltage measuring device (not shown) and the plurality of current measuring devices (233: 233a, 233b, 233c) to digital signals. The transformed digital signals are transmitted to the processing unit (250). A method for transferring the signals is not limited to a wired transmission using a data cable, but the signals may be transferred by a wireless connection.

A power supply (not shown) which is installed inside the first housing (231) transforms the alternating current power supplied from the connection cables (232: 232a, 232b, 232c) in contact manner to power required for operation of the electric power monitoring device (200) to supply the power to the electric power monitoring device (200). That, the power supply is connected to the connection cables (232: 232a, 232b, 232c) and transforms alternating current power flowing the connection cables (232: 232a, 232b, 232c) to direct current power. Also, it transforms the transformed direct current power to power required for each component of the electric power monitoring device (200) to supply operation power to each component. For example, the measurement cable (not shown) for measuring voltages of the connection cables (232: 232a, 232b, 232c) as described above may be used as a power-extracting line. That is, the measurement cable (not shown) connected in contact with the connection cables (232: 232a, 232b, 232c) enables the measurement of voltage and phase as well as the supply of power. If the alternating current power is not supplied from the connection cables (232: 232a, 232b, 232c), operation power is supplied from a cable which is connected to a separate re-chargeable battery installed in the electric power monitoring device (200) to supply the operation power to each component of the electric power monitoring device (200). Also, the power supply (not shown) charges the re-chargeable battery by transforming the alternating current power during the supply of the alternating current power.

The lower housing (231b) comprises a bottom plate having a length extending horizontally and front and rear plates connected to both ends of the bottom plate. The front and rear plates are disposed facing in parallel each other, and an overall form having a curved section of ‘ [symbol] ’-shape is made. The front and rear plates are provided with an opening (238) through their center portion and a plurality of through holes (235) disposed in both sides of the opening (238). The openings (238) of the front and rear plates have a ring shape in which a center portion is opened and a peripheral portion forms a rim. The plurality of through holes (235) are disposed in each of both ends around the opening (238). The connection cables (232: 232a, 232b, 232c) are installed through the openings (238) and connect the first connection portions (210) with one end of the second connection portion (220) through the openings (238). For example, the first connection portion (210) and the second connection portion (220) are connected inside the housing (231b) by the connection cables (232: 232a, 232b, 232c) through the openings (238). Also, the through holes (235) provided in the front and rear plates are connected to the through holes (211) provided in the first and second connection portions (210 and 220) and the through holes (236) provided in the edge plates of the upper housing (231a) using a connecting member (such as bolt and nut). The upper housing (231a) is fitted with the lower housing (231b) and the through holes (235 and 236) provided in the plates of each housing are arranged and coupled using a connecting member (such as bolt and nut) and others. Also, the through holes (235) provided in the front and rear plates of the lower housing (231b) and the through holes (211) provided in the first and second connection portions (210 and 220) are simultaneously arranged and coupled using a connecting member (such as bolt and nut) and others.

The first connection portion (210) is provided with a connector having the same shape as the shape of the input unit (310) provided in the apparatus (300) using alternating current power for supplying the alternating current power. Thus, one end of the first connection portion (210) is connected to the end (110) of the alternating current power line (100) and the other end is securely coupled to the opening (238) provided in the outer region of the front and rear plates of the lower housing (231b) using the through holes (235) and a connection member (such as bolt and nut). The connection cables (232: 232a, 232b, 232c) which are connected to one end of the second connection portion (220) are connected through the opening (238). In embodiments of the present invention, as the first connection portion (210), a female connector with inner 6-pins which is used for semiconductor apparatuses is exemplified. The end (110) of the alternating current power line (100) having a male connector shape with inner 6-pins is coupled to the first connection portion (210) having a female connector shape with inner 6-pins. The inner 6-pins are also coupled to each other. A shape of the first connection portion (210) is not limited to a particular shape, but the shape has preferably the same shape as the shape of the input unit (310), and it may be varied depending on the shape of the input unit (310) provided for supplying alternating current power.

The second connection portion (220) is provided with a connector having the same shape as the end (110) of the alternating current power line (100) for supplying alternating current power to the apparatus (300) using alternating current power. Thus, one end of the second connection portion (220) is connected to the end (310) of the apparatus (300) using alternating current power and the other end is securely coupled to an opening provided in the outer region of a plate with the first connection portion (210) being not fixed among the front and rear plates of the lower housing (231b) using through holes and a connection member (such as bolt and nut). The connection cables (232: 232a, 232b, 232c) which are connected to the first connection portion (210) are connected through the opening. In embodiments of the present invention, as the second connection portion (220), a male connector with inner 6-pins which is used for semiconductor apparatuses is exemplified. The input unit (310) provided for supplying alternating current power having a female connector shape with inner 6-pins is coupled to the second connection portion (220) having a male connector shape with inner 6-pins. The inner 6-pins are also coupled to each other. A shape of the second connection portion (220) is not limited to a particular shape, but the shape has preferably the same shape as the shape of the end (110) of the alternating current power line (100), and it may be varied depending on a shape of the end (110) of the alternating current power line (100) for supplying alternating current power.

In the embodiment described above, the first housing (231) is described as having two members (231a and 231b) coupled with each other, but the shape and configuration of the first housing (231) may be variously altered.

In the embodiment described above, regarding the outer region of the first housing (231: 231a, 231b), the first connection portion (210) is connected to one side, and the second connection portion (220) is connected to the other side. In the embodiment of the present invention, the electric power monitoring device is inserted and installed between the end (110) of the alternating current power line (100) and the input unit (310) of the apparatus (300) using alternating current power, using the first and second connection portions (210 and 220), wherein the input unit (310) supplies alternating current power to the apparatus (300). However, in view of a functionality of the measuring unit (230) of the electric power monitoring device (200), a measurement is performed using the connection cables (232: 232a, 232b, 232c) that connects the first and second connection portions (210 and 220). Therefore, when installing in an apparatus without connection, the electric power monitoring device (200) may be used by inserting and installing between supply cables for alternating current power and input cables of an apparatus using alternating current power, connecting the ends of connection cables (232: 232a, 232b, 232c) to the cable for alternating current power, and connecting the other ends to the input cable of an apparatus using alternating current power. In order to reduce cumbersome works and time required for installation, the electric power monitoring device (200) with the first and second connection portions (210 and 220) is preferably installed.

The rotation unit (240) has a pathway through which various cables pass and a rotational axis around which the processing unit (250) is rotated relative to the measuring unit (230). The rotation unit (240) has also a lower portion which is fixed and an upper portion which can rotate with a rotational axis. The lower portion is connected to a through hole (237) provided in the measuring unit (230), and the upper portion is connected to through holes (254) provided in the processing unit (250). That is, the processing unit (250) can be rotated in right and left directions within a desired angle range (for example, 70 degrees). Also, the rotation unit (240) serves to protect a data cable that connects the measuring unit (230) to the processing unit (250) from exterior impact.

The processing unit (250) is connected to the measuring unit (230) and processes a variety of signals. It comprises a processing circuit board (252) which is installed inside a second housing (251) and connected to the measuring unit (230) by wired or wireless to receive signals measured on alternating current power from a measuring member (such as current measuring device and voltage measuring device) and perform conversion to data, recordation (storage), analysis, literation, data plotting, and data transmission and reception; a memory unit port (such as USB, SD card) which can store the data in the exterior of the electric power monitoring device; a communication port (such as RS232, RF, bluetooth, zigbee) through which the electric power monitoring device can transmit and receive data with other devices (such as electric power monitoring device in a different location or server); and the like. Also, the processing unit (250) is connected to the display (270) which is placed in the interior or exterior of the second housing (251) and displays the data as texts and graphics on a screen.

The second housing (251: 251a, 251b) has an inner space formed by coupling a front housing (251a) and a rear housing (251b). The second housing has the display (270) formed on its front surface and the through holes (254) provided in the other surface(bottom surface) for connection with the rotation unit (240).

The front housing (251a) is a plate having a length extending horizontally and has an opening portion (253) through its center portion through which a portion of the display (270) installed in the inner space of the second housing (251: 251a, 251b) is exposed to outside. The opening portion (253) has a ring shape in which a center portion is opened and a peripheral portion forms a rim. A size of the plate and the opening portion (253) provided in the plate is varied depending on a size of the display (270). That is, the front housing (251a) covers the edge of the display (270). In the embodiment described above, the display installed in the inner space of the second housing (251) is exemplified. However, the display (270) is not limited to installing in the inner space of the second housing (251), but it may be installed in the interior of the first housing (231) or in a separate housing other than the first and second housings (231 and 251).

The rear housing (251b) comprises a backside plate having a length extending horizontally and upper, lower, left and right plates connected to four sides of the backside plate. The upper and lower plates are disposed facing in parallel each other. Also, the left and right plates are disposed facing in parallel each other. That is, one side is fully opened and an inner space is present. The processing circuit board (252) is installed in the inner space, and an opening (259) is provided for a power switch (263) that controls the power of the electric power monitoring device. The upper plate is provided with an opening (257) for a second memory unit port (264) (such as SD memory slot) which is connected to the processing circuit board (252) with a portion of the port being protruded outwardly. The lower plate is provided with the through holes (254) for connection with the rotation unit (240). The right plate is provided with an opening (258) for a first communication port (262) (such as LAN port) which is connected to the processing circuit board (252) with a portion of the port being protruded outwardly. The left plate is provided with an opening (255) for a second communication port (265) (such as RS232 port) which is connected to the processing circuit board (252) with a portion of the port being protruded outwardly and an opening (256) for a first memory unit port (261) (such as USB port). These openings and through holes are not limited to a particular shape and arrangement, but may have various configurations depending on the shape and arrangement of various slots or ports which are connected to the processing circuit board (252) with portions being protruded outwardly from the second housing (251: 251a, 251b).

The processing circuit board (252) is securely installed inside the housing (251: 251a, 251b) of the processing unit (250) using a connection member (such as bolt and nut) and is connected to the display (270). The processing circuit board (252) is provided with the power switch (263), the first communication port (262), first memory unit port (261), the second communication port (265) and the second memory unit port (264). Each of ports is not limited to a particular position on the processing circuit board (252), but they may be freely placed and connected to the processing circuit board (252). Also, each of ports may be fixed to the housing (251: 251a, 251b) of the processing unit (250) and connected to the processing circuit board (252) using a prolonged cable. That is, these ports may be placed at any position on the measuring unit and processing unit housings (231 and 251) of the electric power monitoring device (200).

The display (270) is connected to the processing unit (250). Specifically, it is securely coupled inside the second housing (251: 251a, 251b) using a connection member (such as bolt and nut) and connected to the processing circuit board (252). The display (270) has a common shape, and herein will not be described in detail. The display (270) is not limited to a particular size, but may have various sizes depending on a space where the electric power monitoring device is installed.

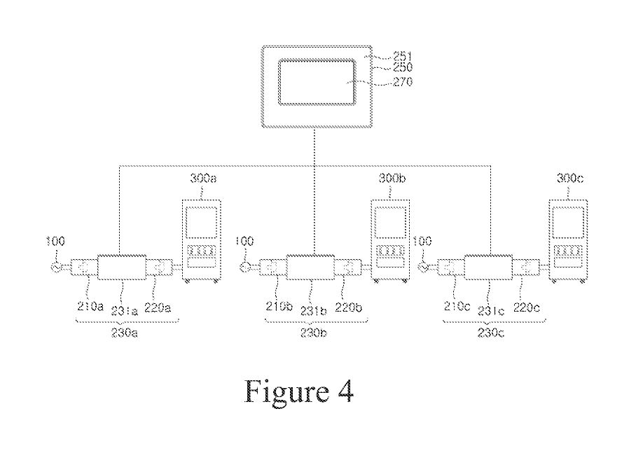

FIG. 4 shows the configuration of an electric power monitoring device according to a modified embodiment of the present invention.

The first housing (231) of the measuring unit (230) is mechanically connected to the second housing (251) of the processing unit (250) using the rotation unit (240) to form the electric power monitoring device (200), but the processing unit (250) may be connected to the measuring unit (230) using a data cable to form the electric power monitoring device (200) in which the processing unit (250) and measuring unit (230) are installed in separate housings spaced apart from each other, as shown in FIG. 4. Also, a relative rotation of the first housing (231) and the second housing (251) by the rotation unit is exemplified, but various motion mechanisms may be installed between the first housing (231) and the second housing (251) to move them in up, down, front and rear directions. For example, the second housing (251) may be coupled to a fixing portion of an arm capable of moving in up, down, left and right directions and the first housing (231) may be connected to an end of the arm which can freely move. Also, the electric power monitoring device (200) in which a plurality of measuring unit (230: 230a, 230b, 230c) are connected to single processing unit (250) may be formed. The connection of the processing unit (250) and the measuring unit (230) may be achieved wired (such as RS232, LAN communication) or wireless (such as RF ID, bluetooth, zigbee, WIFI).

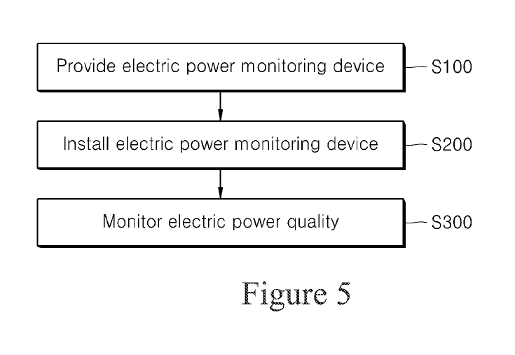

FIG. 5 is a flow chart illustrating a method for monitoring electric power quality according to an embodiment of the present invention.

Now, a method for monitoring electric power quality will be described in detail with reference to FIG. 5.

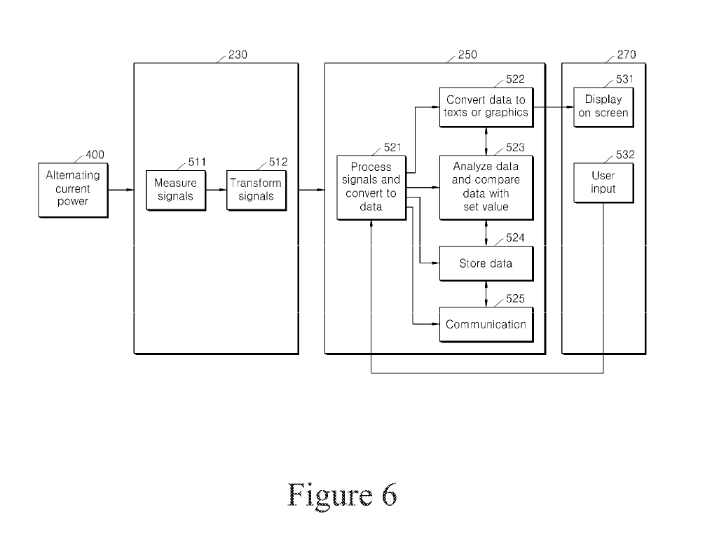

Firstly, an electric power monitoring device is provided (S100 of FIG. 5). The electric power monitoring device comprises a first connection portion that is coupled to a supply line to supply power and a second connection portion that is coupled to an apparatus using the power. The electric power monitoring device is inserted and installed between the supply line for supplying power and the apparatus using the power (S200 of FIG. 5). That is, the first connection portion provided in the electric power monitoring device is connected to the supply line and the second connection portion is connected to the apparatus using power to insert and install the electric power monitoring device between the supply line and the apparatus using power. Then, the electric power monitoring device monitors a quality (such as current, voltage and phase) of power supplied from the supply line (S300 of FIG. 5). Thus, the electric power monitoring device monitors a quality of power supplied from the supply line, and delivers the power to the apparatus using power through the second connection portion. Hereinafter, a method for monitoring electric power quality will be described in detail with reference to FIG. 6.

FIG. 6 is a block diagram illustrating a method for monitoring electric power quality according to an embodiment of the present invention.

The monitoring of electric power quality using an electric power monitoring device as described below is performed in real time.

The measuring unit (230) measures the quality of alternating current power (400). That is, the current, voltage and phase signals of alternating current power (400) are measured (511). Since the measured signals are analog signals, it is difficult to perform signal and data processing. Therefore, the measured signals are converted to digital signals (512). Then, the converted signals are sent to the processing unit (250).

The processing unit (250) receives and processes the converted signals. Effective power, reactive power, apparent power, power factor, frequency, phase difference, energy, and the like are obtained from these current, voltage and phase signals of alternating current power through such processing. Relating to a method for obtaining effective power, reactive power, apparent power, power factor, frequency, phase difference and energy from the current, voltage and phase of alternating current power, such values may be obtained using common formulae, and herein will not be described in detail. The processed signals are converted to data (521).

Then, the data is converted to texts and graphics (522) to display them on a screen.

Also, the data is compared with set values or set ranges pre-inputted from user (523). For example, when a single-phase three-wire or three-phase four-wire system is used and the current of 0.5 Ampere is set as a set value, the electric power monitoring device compares three phases of alternating current supplied with 0.5 Ampere in real time and monitors the alternating current. For example, if a current in one of three phases is greater than 0.5 Ampere or is less than 0.5 Ampere, a user setting condition is not satisfied. Therefore, a warning signal is generated to produce an alarm (such as mark on screen and sound), and a time point when the warning signal is generated and information on a connected apparatus are recorded as log files. The recorded log files may be analyzed into texts and graphs and log files may be compared with each other. Set values or set ranges may be effective power, reactive power, apparent power, power factor, frequency, phase difference, energy values, and the like.

Also, the data is stored in a memory unit embedded in the electric power monitoring device in real time (524). A storage location of the data is not limited to a memory unit embedded in the electric power monitoring device, but it may be stored in an exterior memory unit via a slot and a port for such an exterior memory unit. The data may also be stored in a server connected through a communication port.

Moreover, the data measured in real time may be transmitted and received to/from other devices through a communication port (525). A plurality of the electric power monitoring devices are connected to the server described above through communication ports to control each of the electric power monitoring devices in the server and monitor a plurality of apparatus using alternating current power in real time. Furthermore, a plurality of measuring units may be connected to single processing unit through communication ports.

Values measured for alternating current power may be confirmed as graphs and texts on the display (270). Also, the desired set values may be inputted via the display (270).

The present invention has been described as a way of example such as embodiments, modified embodiments, practice methods and modified methods with reference to the accompanying drawings. However, the present invention is not limited to these embodiments, modified embodiments, practice methods and modified methods. It is to be understood by one with ordinary skill in the art that the present invention may be embodied as various configurations and various combinations of these embodiments and modified embodiments without departing from the spirit and scope of the present invention. Therefore, embodiments described above are merely to exemplify the present invention, but not intended to limit the present invention.

Description of Numerical References

100: alternating current power line 110: end

200: electric power monitoring device 210: first connection portion

220: second connection portion 231: first housing

232: cable 233: current measuring device

234: measurement circuit board 235: through hole

236: through hole 237: through hole

238: opening 240: rotation unit

250: processing unit 251: second housing

252: processing circuit board 255: opening

256: opening 257: opening

258: opening 259: opening

261: first memory unit port 262: first communication port

263: power switch 264: second memory unit port

270: display 300: apparatus using alternating current power

310: input unit 400: alternating current power

511: signal measurement 512: signal transformation

521: signal processing and conversion to data 522: conversion of data to text or graphic

523: data analysis and set value comparison 524: data storage

525: communication 531: screen display

532: user input

1. An electric power monitoring device for use in an apparatus having an alternating current power input unit, comprising
a measuring unit for measuring alternating current power quality, being provided with a first connection portion, a second connection portion and a cable that connects the first connection portion to the second connection portion;
a processing unit which is connected to the measuring unit to convert the measured power quality to data; and
a display which is connected to the processing unit to display the data on a screen.

2. The electric power monitoring device of claim 1, wherein the first connection portion comprises the same shape as the shape of the input unit, and the second connection portion comprises the same shape as the shape of a line for supplying the alternating current power.

3. The electric power monitoring device of claim 1, wherein the measuring unit comprises a current transformer through which the cable passes to measure a current of the alternating current power and a measurement cable which is connected to the cable to measure a voltage of the alternating current power.

4. The electric power monitoring device of claim 3, wherein the measuring unit comprises a measuring unit housing accommodating the current transformer and the measurement cable.

5. The electric power monitoring device of claim 4, comprising a processing unit housing accommodating at least a portion of the processing unit and to mount the display on its one side, which is rotatably connected to the measuring unit housing.

6. The electric power monitoring device of claim 3, wherein the measuring unit and the processing unit are accommodated within separate housings spaced apart from each other.

7. The electric power monitoring device of claim 5, wherein a rotation unit with a rotational axis is coupled between the measuring unit housing and the processing unit housing.

8. The electric power monitoring device of claim 7, wherein the processing unit comprises at least one of memory unit and communication ports that are disposed within the processing unit housing with one end extending outwardly from the processing unit housing.

9. The electric power monitoring device of claim 8, wherein a power supply for supplying power is disposed within the measuring unit housing with one end being connected to the cable.

10. The electric power monitoring device of claim 1, wherein the measuring unit and the processing unit are connected wired, or wireless.

11. The electric power monitoring device of claim 10, wherein a plurality of the measuring units are provided, and the processing unit is connected to the plurality of the measuring units.

12. A device using alternating current power, comprising an apparatus which uses alternating current power and has an input unit connected to the alternating current power, and an electric power monitoring device which is removably connected between a line for supplying the alternating current power and the input unit to monitor the quality of the alternating current power.

13. The device using alternating current power of claim 12, wherein the electric power monitoring device comprises a measuring unit having a first connection portion coupled to the line and a second connection portion coupled to the input unit.

14. The device using alternating current power of claim 13, wherein the measuring unit comprises a measuring unit housing, a cable that is disposed within the measuring unit housing and connected to the first and second connection portions, a non-contact type current measuring device for measuring a current from the cable, and a contact type voltage measuring device for measuring a voltage from the cable.

15. The device using alternating current power of claim 14, wherein the electric power monitoring device comprises a processing unit housing accommodating at least a portion of a processing unit and to mount a display on its one side, which is rotatably connected to the measuring unit housing.
